(19) United States
(12) Patent Application Publication
(10) Pub. No.: US 2011/0115513 A1
(43) Pub. Date: May 19, 2011

(54) WAFER PROBER AND FAILURE ANALYSIS METHOD USING THE SAME

(75) Inventor: Tamotsu Harada, Oita-shi (JP)

(73) Assignee: KABUSHIKI KAISHA TOSHIBA, Tokyo (JP)

(21) Appl. No.: 12/796,177

(22) Filed: Jun. 8, 2010

(30) Foreign Application Priority Data
Nov. 13, 2009 (JP) 2009-259894

(51) Int. Cl. G01R 31/02; G01R 31/20; G01R 1/067

(52) U.S. Cl. 324/754.08; 324/755.01

(57) ABSTRACT

According to one embodiment, a wafer prober for conducting a backside analysis on a wafer is provided. The wafer prober includes a wafer stage and a movable plate. The wafer stage includes surface and back opposed in a thickness direction, a concave portion provided at the surface which supports the wafer, and a first through hole which passes through a bottom face of the concave portion in the thickness direction in the concave portion. The movable plate is accommodated in the concave portion of the wafer stage. The movable plate is movable in a direction parallel to a top face of the wafer stage. The movable plate has a thickness equivalent to a depth of the concave portion of the wafer stage. The movable plate has a second through hole. The second through hole passes through the movable plate in a thickness direction. The second through hole is smaller than the first through hole. The second through hole communicates with the first through hole.

### CROSS-REFERENCE TO RELATED APPLICATION

This application is based upon and claims the benefit of priority from the prior Japanese Patent Application No. 2009-259894 filed on Nov. 13, 2009, the entire contents of which are incorporated herein by reference.

### FIELD

Embodiments described herein relate generally to a wafer prober, and a failure analysis method using the wafer prober.

### BACKGROUND

As one of failure analysis methods for semiconductor devices, a method called emission analysis (light emission analysis) is known. In the emission analysis, an emission microscopy for observing weak light emitted from a failure place or a place where false operation is caused by an influence of the failure place. When conducting a failure analysis on a semiconductor device having a large number of interconnection layers by using this emission analysis, light emitted from the failure place or the like is intercepted by interconnections and consequently it is extremely difficult to observe light emission from the surface side of the semiconductor device. The same is true of other failure analysis methods using light, such as the OBIC (Optical Beam Induced Current) method and the OBIRCH (Optical Beam Induced Resistance CHange) method, as well. Because laser light irradiated from the outside of the semiconductor device is intercepted by interconnections and consequently the laser light does not arrive a desired region in the semiconductor device.

In recent years, the number of interconnection layers in semiconductor devices has increased as the number of layers in semiconductor devices such as system LSIs increases. As a result, it is becoming more and more difficult to conduct a failure analysis from the interconnection layer side (surface side) of the semiconductor device.

Therefore, the necessity for conducting a failure analysis from the back of the semiconductor device (semiconductor substrate side), i.e., the so-called backside analysis is increasing. When conducting the emission analysis by using the backside analysis, light emission is observed from the semiconductor substrate side and consequently light emission can be observed without being intercepted by the interconnection layers.

Furthermore, as the size shrinking of the semiconductor process advances, a failure analysis with high resolution is demanded. As one of high resolution observation techniques, a technique using a solid immersion lens (hereafter also referred to as SIL) is known. In this technique, an optical system (hereafter referred to as SIL system) obtained by combining the SIL with an object lens is used. When conducting the backside analysis by using the SIL, the SIL is brought into close contact with the back of the semiconductor substrate to bring the center of the hemispherical section of the SIL into the observation position. As a result, the numerical aperture (NA) is improved, and observation with high resolution becomes possible.

When conducting the backside analysis using the SIL on a wafer before dicing, it is necessary to provide an opening portion for passing the SIL through it, in a wafer stage on which the wafer is mounted in order to bring the SIL into close contact with the back of the wafer. If it is attempted to secure a sufficient observation visual field, then the opening portion cannot help becoming great as compared with the chip of the analysis object fabricated in the wafer. If such a wide opening portion is provided, then force of the wafer stage applied to support the wafer becomes weak. When a state in which probe needles are brought into contact with electrode pads of a chip (hereafter referred to as probing state) is implemented, the wafer falls into the opening portion because of the needle pressure of the probe needles and warps. As a result, there is a possibility that the probe needles will get out of predetermined electrode pads and the failure analysis will not be able to be conducted stably. Furthermore, there is also a possibility that the wafer will be broken in the worst case.

As means for solving this problem, a support jig which supports the wafer from the back is disclosed (JP-A-2007-324457). This support jig 1 supports a wafer 2 from the back and thereby prevents the wafer 2 from being broken even in a state in which the needle pressure of the probe is applied to the wafer 2. Furthermore, the support jig 1 makes a stage 101 made of quartz glass which is provided in the conventional apparatus unnecessary, and thereby prevents the resolution and measurement sensitivity from being lowered by the thickness of the stage. As for a problem of this technique, however, it is necessary to make a contact portion 11 of the support jig 1 greater than a semiconductor device 21 if it is attempted to secure a sufficient observation visual field with respect to the chip of the analysis object. For example, in the case of large scale semiconductor devices, therefore, a large number of probe needles are fallen onto electrode pads of a chip, and consequently there is a problem that the needle pressure applied to the wafer becomes great and the warp of the wafer cannot be suppressed sufficiently.

### BRIEF DESCRIPTION OF THE DRAWINGS

FIG. 1 is a sectional view of a failure analysis apparatus according to a first embodiment of the present invention;

FIG. 2 is a flow chart for explaining a failure analysis method according to the first embodiment of the present invention;

FIG. 3 is a sectional view of the failure analysis apparatus for explaining a failure analysis method according to the first embodiment of the present invention;

FIG. 4 is a sectional view of the failure analysis apparatus for explaining the failure analysis method according to the first embodiment of the present invention, continued from FIG. 3;

FIG. 5 is a sectional view of the failure analysis apparatus for explaining the failure analysis method according to the first embodiment of the present invention, continued from FIG. 4;

FIG. 6 is a diagram for explaining detailed configurations of a wafer stage and a movable plate according to the first embodiment, in which FIG. 6(a) is a top view of the wafer stage and the movable plate, FIG. 6(b) is a sectional view taken along a line A-A in FIG. 6(a), and FIG. 6(c) is a sectional view taken along a line B-B in FIG. 6(a);

FIG. 7 is a sectional view of a failure analysis apparatus according to a second embodiment of the present invention;

FIG. 8 is a flow chart for explaining a failure analysis method according to the second embodiment of the present invention;

FIG. 9 is a flow chart for explaining a failure analysis method according to a third embodiment of the present invention; and

FIG. 10 is a diagram for explaining detailed configurations of a wafer stage and a movable plate according to a fourth embodiment, in which FIG. 10(a) is a top view of the wafer stage and the movable plate, FIG. 10(b) is a sectional view taken along a line A-A in FIG. 10(a), and FIG. 10(c) is a sectional view taken along a line B-B in FIG. 10(a).

### DETAILED DESCRIPTION

According to one embodiment, a wafer prober for conducting a backside analysis on a wafer is provided. The wafer prober includes a wafer stage and a movable plate. The wafer stage includes surface and back opposed in a thickness direction, a concave portion provided at the surface which supports the wafer, and a first through hole which passes through a bottom face of the concave portion in the thickness direction in the concave portion. The movable plate is accommodated in the concave portion of the wafer stage. The movable plate is movable in a direction parallel to a top face of the wafer stage. The movable plate has a thickness equivalent to a depth of the concave portion of the wafer stage. The movable plate has a second through hole. The second through hole passes through the movable plate in a thickness direction. The second through hole is smaller than the first through hole. The second through hole communicates with the first through hole.

Hereafter, four embodiments according to the present invention will be described with reference to the drawings. In a first embodiment, a wafer prober and a failure analysis method using the wafer prober will be described. In a second embodiment, a wafer prober obtained by adding immersion oil to the wafer prober according to the first embodiment, and a failure analysis method using the wafer prober will be described. In a third embodiment, a failure analysis method in which the wafer supporting force can be further enhanced will be described. In a fourth embodiment, a wafer prober having a configuration which is different from that in the first embodiment will be described.

Incidentally, components having equivalent functions are denoted by like characters, and detailed description of them will not be repeated.

### First Embodiment

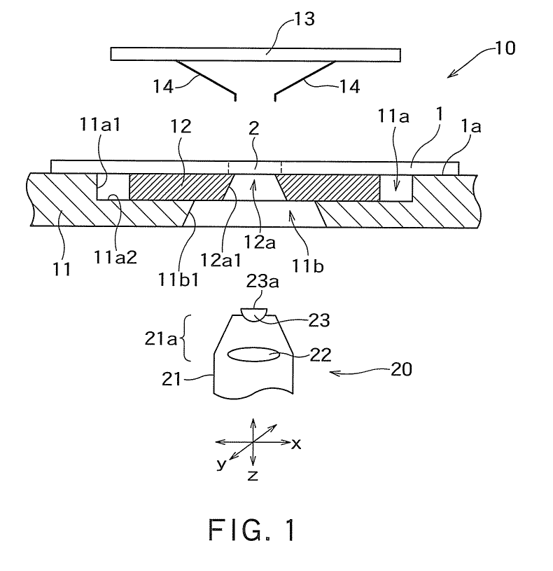

A failure analysis apparatus according to a first embodiment of the present invention will now be described. FIG. 1 illustrates a sectional view of a failure analysis apparatus including a wafer prober 10 and an SIL system 20 according to the first embodiment.

As appreciated from FIG. 1, the wafer prober 10 includes a wafer stage 11, a movable plate 12, a probe card 13, and probe needles 14 fixed to the probe card 13.

The wafer stage 11 includes a concave portion 11a provided at surface which supports a wafer 1, and an opening portion 11b. The concave portion 11a is formed to have a size which makes it possible to place the wafer 1 on the wafer stage 11 and makes it possible for the movable plate 12 described below to move in a sufficiently wide range. Furthermore, as appreciated from FIG. 1, the opening portion 11b which passes through a part of a bottom face 11a2 of the concave portion 11a is provided. The opening portion 11b is formed to have a size which makes it possible to pass the SIL system 20 through it to bring an SIL 23 described below into close contact with a back 1a of the wafer 1 and makes it possible to obtain a sufficient observation visual field.

The movable plate 12 includes an observation port 12a, and the movable plate 12 is disposed on the bottom face 11a2 of the concave portion 11a. The movable plate 12 is accommodated in the concave portion 11a to be able to be moved in a direction (hereafter referred to as x-y direction) parallel to a top face of the wafer stage 11 by a movable plate drive mechanism (not illustrated). As appreciated from FIG. 1, the observation port 12a communicates with the opening portion 11b of the wafer stage 11.

Since the thickness of the movable plate 12 is equal to the height of a side face 11a1 of the concave portion 11a (i.e., depth of the concave portion 11a), a top face of the wafer stage 11 has the same height as a top face of the movable plate 12. As a result, the wafer 1 can be placed on the wafer stage 11 to bring the back 1a of the wafer 1 into contact with the top face of the movable plate 12 and the top face of the wafer stage 11 simultaneously. As appreciated from FIG. 1, therefore, the wafer 1 is supported by not only the wafer stage 11 but also the movable plate 12.

The observation port 12a of the movable plate 12 is formed as a through hole which is smaller than the opening portion 11b of the wafer stage 11. The size of the observation port 12a may be made smaller than that of the chip 2 of the analysis object in order to further suppress the warp of the wafer 1 in the probing state. Preferably, the size of the observation port 12a is set equal to the sum of the diameter of a tip portion 21a of a lens holder 21 and a little margin. In other words, it is preferable that the observation port 12a is worked to a shape which lies parallel with the tip portion 21a of the lens holder 21.

Incidentally, it is preferable to form the observation port 12a and the opening portion 11b in a tapered shape which gradually shrinks in diameter as the position approaches the top face as illustrated in FIG. 1. By doing so, the area of the top face of the movable plate 12 and the area of the bottom face 11a2 of the wafer stage 11 can be made further greater and force for supporting the wafer 1 can be enhanced.

The probe card 13 is disposed above the wafer stage 11. A plurality of probe needles 14 is fixed to the probe card 13.

The SIL system 20 is disposed below the wafer prober 10. The SIL system 20 includes a lens holder 21, an object lens 22, and an SIL (solid immersion lens) 23. The SIL system 20 can be moved in a direction (x-y direction) parallel to the top face of the wafer stage 11 and in a direction (hereafter referred to as z direction) perpendicular to the top face of the wafer stage 11 by an SIL system drive part (not illustrated). Incidentally, an SIL system used for the backside analysis intended for a package on which a chip is mounted can be used as the SIL system 20 in the present embodiment as it is.

As appreciated from FIG. 1, the tip portion 21a of the lens holder 21 is preferably formed in the tapered shape in order to accommodate the SIL 23 and the object lens 22 which is larger in diameter than the SIL 23. The wafer supporting force can be enhanced by providing the tip portion 21a with a tapered shape to make the area of the top face of the movable plate 12 wide as far as possible. As a result, the warp of the wafer 1 in the probing state can be suppressed.

Incidentally, the SIL 23 is, for example, a hemispherical silicon lens. As for the shape of the SIL 23, a hyper-hemispherical type called Weierstrass sphere is typical besides the hemispherical type. As for the material of the SIL 23, the same material as that of the semiconductor substrate (wafer 1), or a material having a refractive index close to that of the semiconductor substrate is used. This aims at maintaining the numerical aperture by avoiding refraction at the interface between the SIL 23 and the wafer 1.

The lens holder 21 holds the SIL 23 at its tip, and holds the object lens 22 within it. As appreciated from FIG. 1, the lens holder 21 holds the SIL 23 with a hemispherical section 23a of the SIL 23 being opposed to the wafer 1.

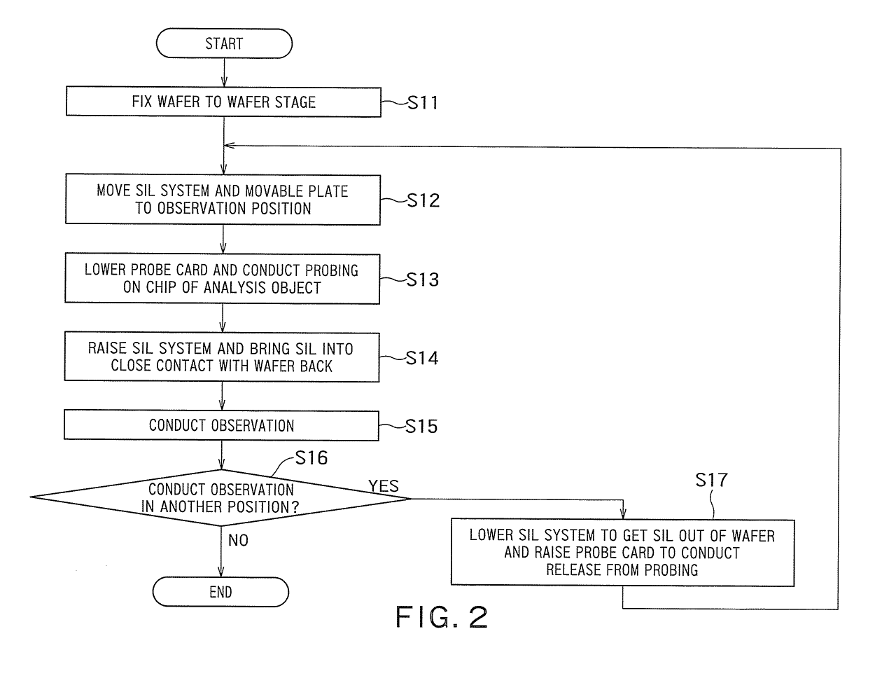

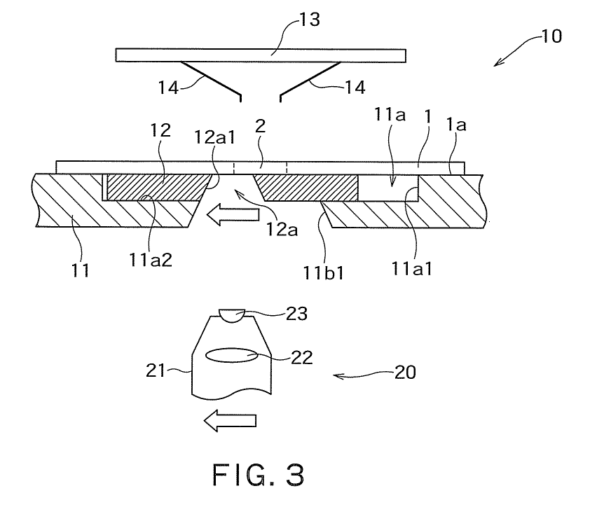

A procedure of the backside analysis using the failure analysis apparatus according to the first embodiment will now be described along the flow chart illustrated in FIG. 2 with reference to FIGS. 3 to 5.

(1) First, the wafer 1 on which the chip 2 of the analysis object is fabricated is placed on the wafer stage 11 and the movable plate 12 to bring the back 1a of the wafer 1 into contact with the top faces of the wafer stage 11 and the movable plate 12 (i.e., cause the back 1a of the wafer 1 to be opposed to the downside in FIG. 1). Thereafter, the wafer 1 is fixed to the wafer stage 11 by means such as a vacuum chuck (step S11). Incidentally, before fixing the wafer 1, fine adjustment of the position of the wafer 1 is conducted to bring the probe needles 14 into contact with predetermined electrode pads when the probe card 13 is lowered.

(2) Then, as appreciated from FIG. 3, the SIL 23 and the observation port 12a are positioned right below the observation position of the chip 2 by moving the SIL system 20 and the movable plate 12 jointly in the x-y direction (step S12).

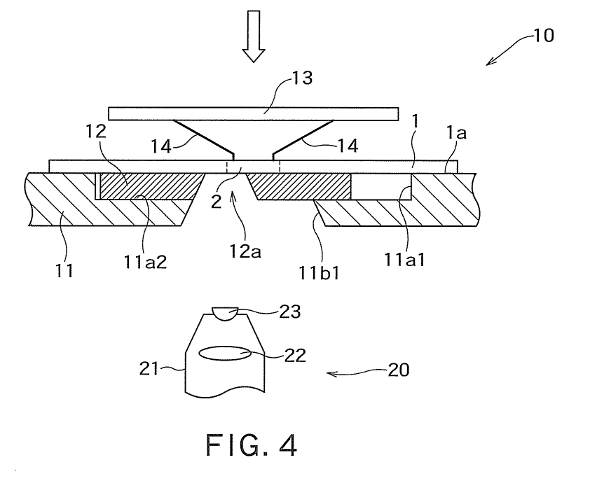

(3) Then, as appreciated from FIG. 4, the probe needles 14 are brought into contact with the predetermined electrodes on the chip 2 by lowering the probe card 13 toward the wafer 1 (step S13). At this time, needle pressure of the probe needles 14 is applied to the wafer 1. Since the wafer 1 is supported by not only the wafer stage 11 but also the movable plate 12, however, warp of the wafer 1 can be suppressed.

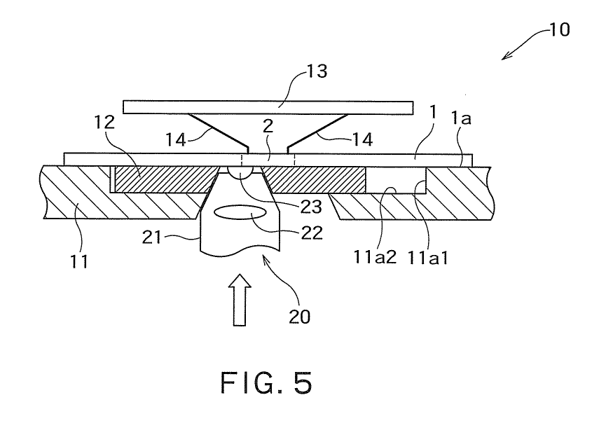

(4) Then, as appreciated from FIG. 5, the SIL 23 is passed through the observation port 12a to bring the SIL 23 into close contact with the back 1a of the wafer 1 by raising the SIL system 20 toward the wafer prober 10 (step S14).

(5) Then, observation is conducted (step S15). More specifically, a failure in the chip 2 is made to reappear by applying a test pattern signal to an electronic circuit in the chip 2 via the probe needles 14. Then, light emission from the chip 2 in the failure reappearance state is observed by using the SIL system 20.

(6) After the observation is finished, a determination is made whether to conduct observation in another position of the chip 2 (step S16). When conducting the observation in another position, the SIL system 20 is lowered to get the SIL 23 out of the wafer 1 and the probe card 13 is raised to conduct release from the probing (step S17). The processing returns to the step S12. On the other hand, when not conducting observation in another position, the observation is finished. Incidentally, when observing another chip fabricated on the wafer 1 after observation of a certain chip 2 is finished, the wafer 1 is shifted to bring the probe needles 14 into contact with predetermined electrode pads when the probe card 13 is lowered. Then, observation is conducted in the same way as the above-described method.

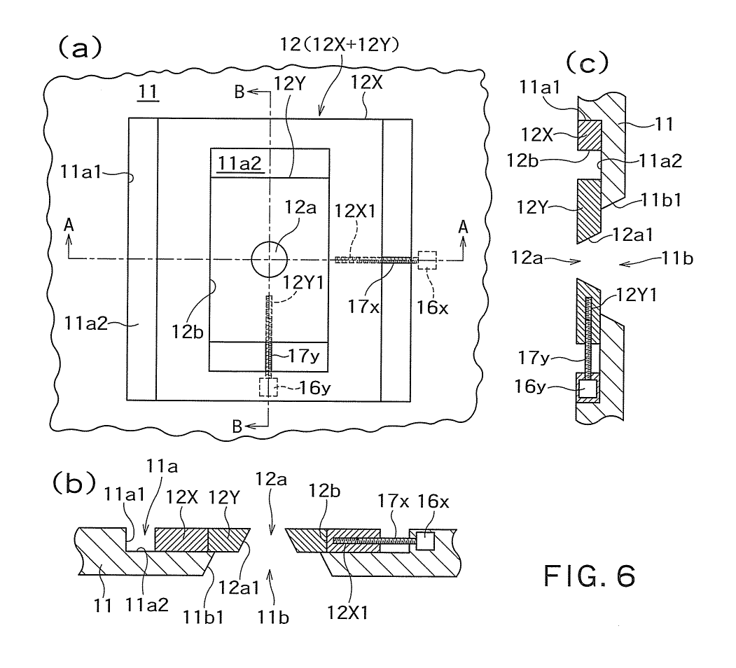

A configuration example of the wafer stage 11 and the movable plate 12 will now be described with reference to FIG. 6. FIG. 6(a) illustrates a top view of the wafer stage 11 and the movable plate 12. FIG. 6(b) is a sectional view taken along a line A-A in FIG. 6(a). FIG. 6(c) is a sectional view taken along a line

B-B in FIG. 6(a).

The movable plate 12 includes an x-axis movable plate 12X and a y-axis movable plate 12Y. As appreciated from FIGS. 6(a) to 6(c), the x-axis movable plate 12X includes an accommodating hole 12b for accommodating the y-axis movable plate 12Y. A screw hole 12X1 is provided in the x-axis movable plate 12X in the x-axis direction. A threaded motor shaft 17x is screwed into the screw hole 12X1. A motor 16x which rotates the motor shaft 17x is fixed to the wafer stage 11. The motor 16x rotates the motor shaft 17x according to a movement quantity of the x-axis movable plate 12X.

As appreciated from FIGS. 6(a) to 6(c), the y-axis movable plate 12Y is disposed to be fitted movably along the y-axis into the accommodating hole 12b which is provided in the x-axis movable plate 12X. A screw hole 12Y1 is provided in the y-axis movable plate 12Y in the y-axis direction. A threaded motor shaft 17y is screwed into the screw hole 12Y1. A motor 16y which rotates the motor shaft 17y is fixed to the x-axis movable plate 12X. The motor 16y rotates the motor shaft 17y according to a movement quantity of the y-axis movable plate 12Y.

The observation port 12a can be moved to a desired position in the horizontal plane by forming the movable plate 12 as described above.

As described heretofore, the wafer prober 10 according to the present embodiment includes the movable plate 12 which is disposed in the concave portion 11a of the wafer stage 11 to be movable in the x-y direction. Viewed from another angle, it can be grasped that the wafer stage is formed of a stationary part (the wafer stage 11) and a movable part (the movable plate 12).

The observation port 12a provided through the movable plate 12 to pass the SIL 23 through it is formed narrower than the opening portion 11b of the wafer stage 11. In the probing state, therefore, the warp of the wafer 1 in the observation port 12a can be suppressed. As a result, the wafer 1 is prevented from being broken, and the probe needles do not get out of the electrode pads of the analysis object, resulting in a stable failure analysis.

Furthermore, the movable plate 12 is provided, thereby, the observation port 12a can be moved freely according to the observation position. As a result, according to the present embodiment, an observation visual field which can observe the whole region of the chip of the analysis object without moving the wafer 1 can be ensured.

In other words, according to the present embodiment, the warp of the wafer in the probing state can be suppressed as far as possible and a sufficient observation visual field can be obtained.

### Second Embodiment

A failure analysis apparatus according to a second embodiment of the present invention will now be described. One of differences of the second embodiment from the first embodiment is that immersion oil (optical oil) is applied on the top face of the movable plate 12. As a result, friction caused between the movable plate 12 and the wafer 1 when the movable plate 12 moves in the x-y direction is reduced. Accordingly, the movable plate 12 can be moved in the x-y direction while staying in the probing state.

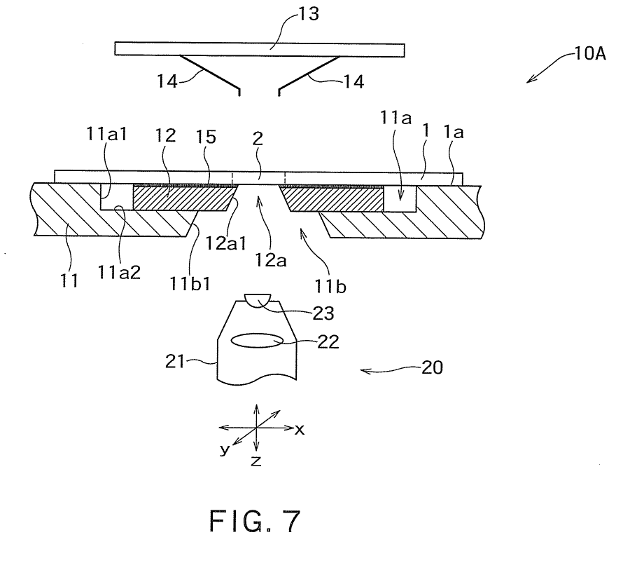

FIG. 7 illustrates a sectional view of a failure analysis apparatus including a wafer prober 10A and the SIL system 20 according to a second embodiment of the present invention. As appreciated from FIG. 7, immersion oil 15 is applied onto the top face of the movable plate 12 of the wafer prober 10A. In the configuration example illustrated in FIG. 6, the immersion oil 15 is applied onto the x-axis movable plate 12X and the y-axis movable plate 12Y. Because of existence of the immersion oil 15 between the movable plate 12 and the wafer 1, the friction caused between the wafer 1 and the movable plate 12 when the movable plate 12 moves is reduced.

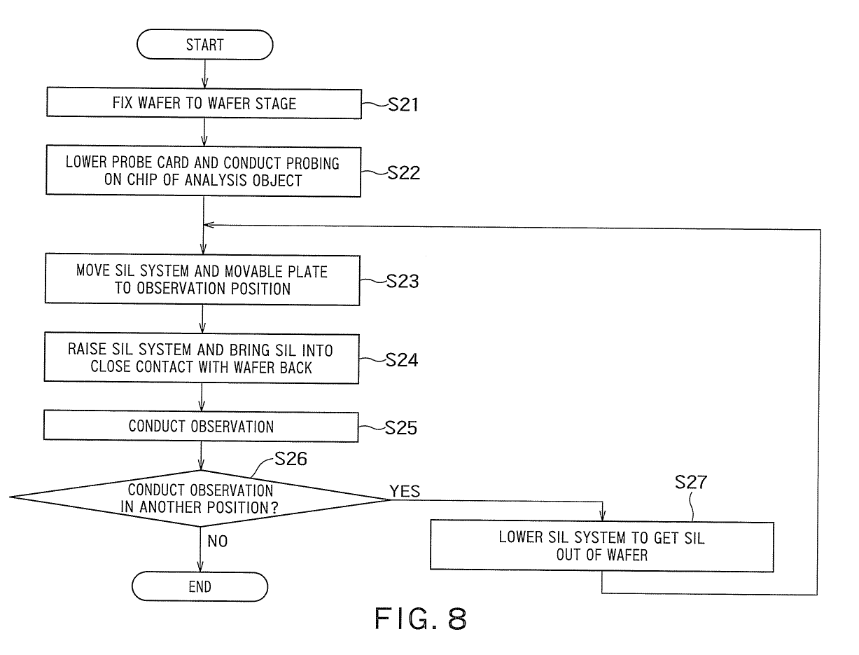

A procedure of the backside analysis using the failure analysis apparatus according to the second embodiment will now be described along a flow chart illustrated in FIG. 8.

(1) First, the wafer 1 is fixed onto the wafer stage 11 in the same way as the step S11 in the first embodiment (step S21).

(2) Then, the probe needles 14 are brought into contact with predetermined electrodes on the chip 2 by lowering the probe card 13 toward the wafer 1 (step S22).

(3) Then, the SIL 23 and the observation port 12a are positioned right below the observation position of the chip 2 by moving the SIL system 20 and the movable plate 12 jointly in the x-y direction (step S23). Because of the immersion oil 15 applied to the top face of the movable plate 12, the movable plate 12 can be moved while staying in the probing state at this time.

(4) Then, the SIL 23 is passed through the observation port 12a to bring the SIL 23 into close contact with the back 1a of the wafer 1 by raising the SIL system 20 toward the wafer prober 10 (step S24).

(5) Then, observation is conducted in the same way as the step S15 in the first embodiment (step S25).

(6) After the observation is finished, a determination is made whether to conduct observation in another position of the chip 2 (step S26). When conducting the observation in another position, the SIL system 20 is lowered to get the SIL 23 out of the wafer 1 (step S27). Then, the processing returns to the step S23. On the other hand, when not conducting observation in another position, the observation is finished.

In the present embodiment, the immersion oil 15 is applied to the top face of the movable plate 12 as heretofore described. As a result, friction caused between the movable plate 12 and the back 1a of the wafer 1 when the movable plate 12 moves in the x-y direction is reduced. Accordingly, it becomes possible to move the movable plate 12 while staying in the probing state and change the observation position. As a result, it becomes unnecessary to raise or lower the probe card 13 when changing the observation position and consequently the efficiency of the failure analysis can be improved. In addition, deterioration of the electrode pads caused by repetition of the probing can be prevented.

### Third Embodiment

A failure analysis method according to a third embodiment of the present invention will now be described. One of differences of the third embodiment from the first embodiment is that the wafer is supported by not only the wafer stage and the movable plate but also the SIL by raising the SIL system and bringing the SIL into close contact with the wafer before bringing probe needles into contact with predetermined electrode pads on the chip, i.e., probing. As a result, it becomes possible for the wafer to withstand a greater load. Therefore, a greater number of probe needles can be brought into contact with the chip.

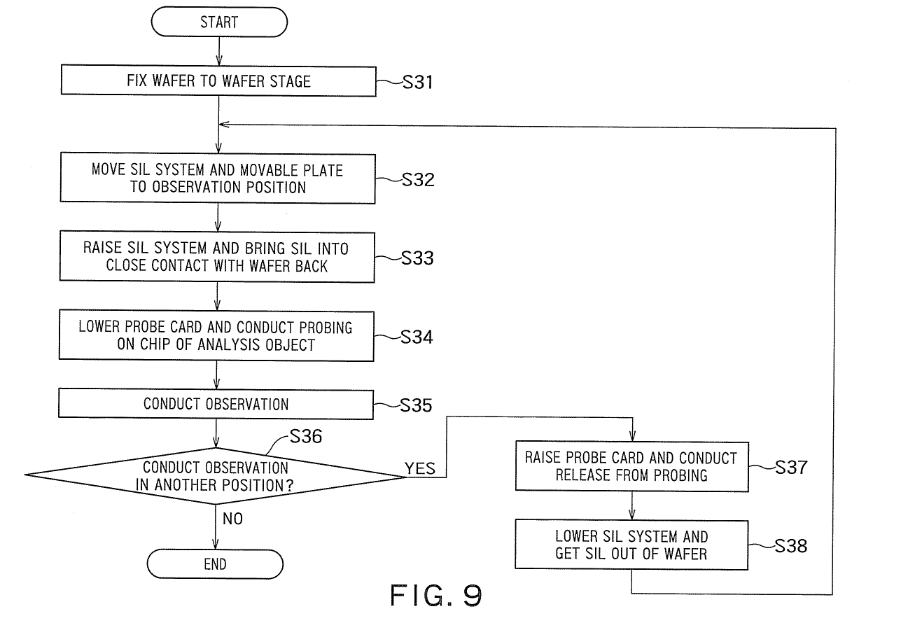

A procedure of the backside analysis using the failure analysis apparatus according to the third embodiment will now be described along a flow chart illustrated in FIG. 9.

(1) First, the wafer 1 is fixed onto the wafer stage 11 in the same way as the step S11 described in the first embodiment (step S31).

(2) Then, the SIL 23 and the observation port 12a are positioned right below the observation position of the chip 2 by moving the SIL system 20 and the movable plate 12 jointly in the x-y direction (step S32).

(3) Then, the SIL 23 is passed through the observation port 12a to bring the SIL 23 into close contact with the back is of the wafer 1 by raising the SIL system 20 toward the wafer prober 10 (step S33).

(4) Then, the probe needles 14 are brought into contact with predetermined electrodes on the chip 2 by lowering the probe card 13 toward the wafer 1 in the same way as the step S13 in the first embodiment (step S34).

(5) Then, observation is conducted in the same way as the step S15 in the first embodiment (step S35).

(6) After the observation is finished, a determination is made whether to conduct observation in another position (step S36). When conducting the observation in another position, the probe card 13 is raised to conduct release from the probing (step S37) and then the SIL system 20 is lowered to get the SIL 23 from the wafer 1 (step S38). Then, the processing returns to the step S32. On the other hand, when not conducting observation in another position, the observation is finished.

In the present embodiment, the SIL system 20 is raised and can bring the SIL 23 into close contact with the wafer 1 before the probing as described heretofore. According to the present embodiment, therefore, the wafer 1 is supported by not only the wafer stage 11 and the movable plate 12 but also the SIL 23 (SIL system 20). As a result, the warp of the wafer 1 in the probing state can be further suppressed. Even if the number of the probe needles is greater, i.e., the load of the probing is heavier, therefore, it becomes possible to maintain the probing state and conduct stable failure analysis and the wafer can be prevented from being broken.

### Fourth Embodiment

A wafer stage and a movable plate according to a fourth embodiment will now be described. One of differences of the fourth embodiment from the first embodiment is that the movable plate is not accommodated in the concave portion but is accommodated in the accommodation hole so as to pass through the wafer stage. Although details will be described below, a shaft portion of the movable plate fits movably into a shaft hole provided on a side face of an accommodation hole of the wafer stage. As a result, the movable plate is held to be movable by the wafer stage.

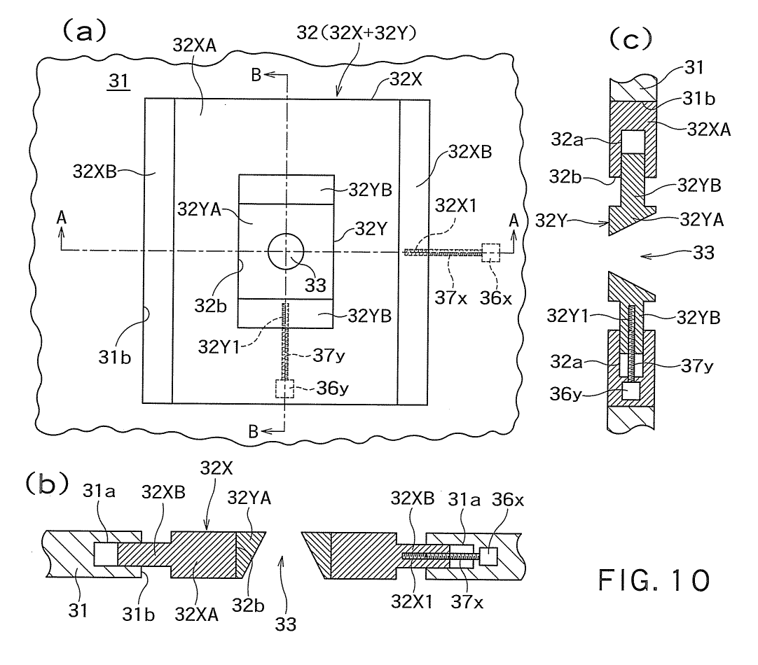

Hereafter, details will be described with reference to FIG. 10. FIG. 10(a) illustrates a top view of a wafer stage 31 and a movable plate 32 according to the present embodiment. FIG. 10(b) is a sectional view taken along a line A-A in FIG. 10(a). FIG. 10(c) is a sectional view taken along a line B-B in FIG. 10(a).

The wafer stage 31 has an accommodation hole 31b to accommodate the movable plate 32. Furthermore, as appreciated from FIG. 10(b), a shaft hole 31a which extends in the x-axis direction is provided on a side face of the accommodation hole 31b.

The movable plate 32 includes an x-axis movable plate 32X which can move in the x-axis direction (horizontal direction in FIG. 10(a)) and a y-axis movable plate 32Y which can move in the y-axis direction (vertical direction in FIG. 10(a)).

The x-axis movable plate 32X includes a main body portion 32XA and shaft portions 32XB and 32XB provided at both ends of the main body portion 32XA. As appreciated from FIGS. 10(a) to 10(c), the main body portion 32XA includes an accommodation hole 32b to accommodate the y-axis movable plate 32Y. The shaft portion 32XB fits movably along the x-axis into the shaft hole 31a provided in the wafer stage 31, and the x-axis movable plate 32X is held by the wafer stage 31 so as to be movable in the x-axis direction. A screw hole 32X1 is provided in the shaft portion 32XB, and a threaded motor shaft 37x is screwed into the screw hole 32X1. A motor 36x which rotates the motor shaft 37x is fixed to the wafer stage 31. The motor 36x rotates the motor shaft 37x according to a desired movement quantity of the x-axis movable plate 32X. As a result, the x-axis movable plate 32X moves in the x-axis direction.

The y-axis movable plate 32Y includes a main body portion 32YA and shaft portions 32YB and 32YB provided at both ends of the main body portion 32YA. As appreciated from FIGS. 10(a) to 10(c), an observation port 33 which passes through the main body portion 32YA is provided nearly in the center of the main body portion 32YA. The shaft portion 32YB fits movably along the y-axis into a shaft hole 32a provided in the main body portion 32XA of the x-axis movable plate 32X, and the y-axis movable plate 32Y is held by the x-axis movable plate 32X so as to be movable in the y-axis direction. A screw hole 32Y1 is provided in the shaft portion 32YB, and a threaded motor shaft 37y is screwed into the screw hole 32Y1. A motor 36y which rotates the motor shaft 37y is fixed to the x-axis movable plate 32X. The motor 36y rotates the motor shaft 37y according to a desired movement quantity of the y-axis movable plate 32Y. As a result, the y-axis movable plate 32Y moves in the y-axis direction.

The top face of the movable plate 32 (32X+32Y) and the top face of the wafer stage 31 have the same height and form an even face. As a result, the wafer placed and fixed on the wafer stage 31 is supported by not only the wafer stage 31 but also the movable plate 32.

As appreciated from FIGS. 10(b) to 10(c), the observation port 33 is formed in a tapered shape which gradually shrinks in diameter as the position approaches the top face (wafer placing face) of the movable plate 32. Accordingly, the area of the top face of the movable plate 32 is made great as far as possible, and the force for supporting the wafer 1 is enhanced. As a result, the warp of the wafer 1 in the probing state can be suppressed.

The wafer stage 31 and the movable plate 32 having the above-described configuration can move the observation port 33 to a desired position in the horizontal plane.

Incidentally, the failure analysis method described in the first to third embodiments can be conducted by using the wafer stage 31 and the movable plate 32 according to the present embodiment.

Heretofore, the four embodiments according to the present invention have been described. The present invention is not limited to the case of the emission analysis, but can also be applied to backside analysis methods using other light. For example, the present invention can also be applied to a backside analysis method in which changes in device characteristics are observed by laser irradiation, such as the OBIC method, OBIRCH method, DLS (Dynamic Laser Stimulation) method and SLS (Static Laser Stimulation) method. In these cases, a predetermined position of the wafer back is irradiated with laser light via the object lens 22 and the SIL 23.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the sprit of the inventions. The accompanying claims and their equivalents are intended to cover such forms or modifications as would fall within the scope and sprit of the invention.

1. A wafer prober for conducting a backside analysis on a wafer, the wafer prober comprising:
a wafer stage having surface and back opposed in a thickness direction, a concave portion provided at the surface which supports the wafer, and a first through hole which passes through a bottom face of the concave portion in the thickness direction; and
a movable plate accommodated in the concave portion of the wafer stage, the movable plate being movable in a direction parallel to a top face of the wafer stage, the movable plate having a thickness equivalent to a depth of the concave portion of the wafer stage, the movable plate having a second through hole, the second through hole passing through the movable plate in a thickness direction, the second through hole being smaller than the first through hole, and the second through hole communicating with the first through hole.

2. The wafer prober according to claim 1, wherein the second through hole takes a shape which runs along a lens holder having a solid immersion lens at a tip thereof.

3. The wafer prober according to claim 1, wherein the second through hole takes a tapered shape which gradually shrinks in diameter as the position approaches a top face of the movable plate.

4. The wafer prober according to claim 1, wherein the movable plate includes:
an x-axis movable plate having an accommodation hole passing through in a thickness direction thereof, the x-axis movable plate being configured to be able to be moved in an x-axis direction by a first motor fixed to the wafer stage; and
a y-axis movable plate having the second through hole, the y-axis movable plate being accommodated in the accommodation hole of the x-axis movable plate, the y-axis movable plate being configured to be capable of being moved in a y-axis direction by a second motor fixed to the x-axis movable plate.

5. The wafer prober according to claim 4, further comprising immersion oil applied to top faces of the x-axis movable plate and the y-axis movable plate.

6. A failure analysis method using the wafer prober according to claim 1, the failure analysis method comprising:
placing the wafer on the wafer stage and the movable plate to bring a back of the wafer into contact with top faces of the wafer stage and the movable plate;
moving an SIL system, which is disposed below the wafer prober and which has a lens holder having a solid immersion lens at a tip thereof and an object lens within it, and the movable plate jointly and thereby positioning the solid immersion lens and the second through hole right below an observation position in a chip fabricated on the wafer;
lowering a probe card disposed above the wafer stage and having probe needles fixed thereto toward the wafer and thereby bringing the probe needles into contact with predetermined electrode pads on the chip; and
raising the SIL system toward the wafer prober to pass the solid immersion lens through the second through hole of the movable plate and bring the solid immersion lens into close contact with the back of the wafer.

7. A failure analysis method using the wafer prober according to claim 1, the failure analysis method comprising:
placing the wafer on the wafer stage and the movable plate to bring a back of the wafer into contact with top faces of the wafer stage and the movable plate;
moving an SIL system, which is disposed below the wafer prober and which includes a lens holder having a solid immersion lens at a tip thereof and an object lens within it, and the movable plate jointly and thereby positioning the solid immersion lens and the second through hole right below an observation position in a chip fabricated on the wafer;
raising the SIL system toward the wafer prober, passing the solid immersion lens through the second through hole of the movable plate, and bringing the solid immersion lens into close contact with the back of the wafer; and
in a state in which the solid immersion lens is in close contact with the back of the wafer, lowering a probe card disposed above the wafer stage and having probe needles fixed thereto toward the wafer and thereby bringing the probe needles into contact with predetermined electrode pads on the chip.

8. The wafer prober according to claim 1, further comprising immersion oil applied to a top face of the movable plate.

9. The wafer prober according to claim 8, wherein the second through hole takes a tapered shape which gradually shrinks in diameter as the position approaches the top face of the movable plate.

10. A failure analysis method using the wafer prober according to claim 8, the failure analysis method comprising:
placing the wafer on the wafer stage and the movable plate to bring a back of the wafer into contact with top faces of the wafer stage and the movable plate;
lowering a probe card disposed above the wafer stage and having probe needles fixed thereto toward the wafer and thereby bringing the probe needles into contact with predetermined electrode pads on the chip fabricated on the wafer;
in a state in which the probe needles are in contact with the predetermined electrode pads of the chip, moving an SIL system, which is disposed below the wafer prober and which includes a lens holder having a solid immersion lens at a tip thereof and an object lens within it, and the movable plate jointly and thereby positioning the solid immersion lens and the second through hole right below an observation position in a chip fabricated in the wafer; and
raising the SIL system toward the wafer prober to pass the solid immersion lens through the second through hole of the movable plate and bring the solid immersion lens into close contact with the back of the wafer.

11. A wafer prober for conducting a backside analysis on a wafer, the wafer prober comprising:
a wafer stage having surface and back opposed in a thickness direction, a first accommodation hole which passes through the wafer stage in the thickness direction, and a first shaft hole which extends from a side face of the first accommodation hole in an x-axis direction; and
a movable plate accommodated in the first accommodation hole, the movable plate being movable in an x-y direction, the movable plate having a thickness equivalent to a depth of the first accommodation hole of the wafer stage,
the movable plate including:
an x-axis movable plate accommodated in the first accommodation hole of the wafer stage and configured to be movable in an x-axis direction, the x-axis movable plate including a first shaft portion which fits movably into the first shaft hole of the wafer stage and a first main body portion having a second accommodation hole, the x-axis movable plate including a second shaft hole which extends from a side face of the second accommodation hole in a y-axis direction; and
a y-axis movable plate accommodated in the second accommodation hole of the x-axis movable plate and configured to be movable in a y-axis direction, the y-axis movable plate including a second shaft portion which fits movably into the second shaft hole of the x-axis movable plate, the y-axis movable plate including a second main body portion having an observation port which passes through the y-axis movable plate in a thickness direction.

12. The wafer prober according to claim 11, wherein the observation port takes a shape which runs along a lens holder having a solid immersion lens at a tip thereof.

13. The wafer prober according to claim 11, wherein the observation port takes a tapered shape which gradually shrinks in diameter as the position approaches a top face of the movable plate.

14. The wafer prober according to claim 11, wherein
the x-axis movable plate is driven by a first motor fixed to the wafer stage, and
the y-axis movable plate is driven by a second motor fixed to the x-axis movable plate.

15. The wafer prober according to claim 14, further comprising immersion oil applied to top faces of the x-axis movable plate and the y-axis movable plate.

16. A failure analysis method using the wafer prober according to claim 11, the failure analysis method comprising:
placing the wafer on the wafer stage and the movable plate to bring a back of the wafer into contact with top faces of the wafer stage and the movable plate;
moving an SIL system, which is disposed below the wafer prober and which includes a lens holder having a solid immersion lens at a tip thereof and an object lens within it, and the movable plate jointly and thereby positioning the solid immersion lens and the observation port right below an observation position in a chip fabricated on the wafer;
lowering a probe card disposed above the wafer stage and having probe needles fixed thereto toward the wafer and thereby bringing the probe needles into contact with predetermined electrode pads on the chip; and
raising the SIL system toward the wafer prober to pass the solid immersion lens through the observation port and bring the solid immersion lens into close contact with the back of the wafer.

17. A failure analysis method using the wafer prober according to claim 11, the failure analysis method comprising:
placing the wafer on the wafer stage and the movable plate to bring a back of the wafer into contact with top faces of the wafer stage and the movable plate;
moving an SIL system, which is disposed below the wafer prober and which includes a lens holder having a solid immersion lens at a tip thereof and an object lens within it, and the movable plate jointly and thereby positioning the solid immersion lens and the second through hole right below an observation position in a chip fabricated on the wafer;
raising the SIL system toward the wafer prober, passing the solid immersion lens through the observation port of the movable plate, and bringing the solid immersion lens into close contact with the back of the wafer; and
in a state in which the solid immersion lens is in close contact with the back of the wafer, lowering a probe card disposed above the wafer stage and having probe needles fixed thereto toward the wafer and thereby bringing the probe needles into contact with predetermined electrode pads on the chip.

18. The wafer prober according to claim 11, further comprising immersion oil applied to a top face of the movable plate.

19. The wafer prober according to claim 18, wherein the observation port takes a tapered shape which gradually shrinks in diameter as the position approaches the top face of the movable plate.

20. A failure analysis method using the wafer prober according to claim 18, the failure analysis method comprising:
placing the wafer on the wafer stage and the movable plate to bring a back of the wafer into contact with top faces of the wafer stage and the movable plate;
lowering a probe card disposed above the wafer stage and having probe needles fixed thereto toward the wafer and thereby bringing the probe needles into contact with predetermined electrode pads on the chip fabricated on the wafer;
in a state in which the probe needles are in contact with the predetermined electrode pads of the chip, moving an SIL system, which is disposed below the wafer prober and which includes a lens holder having a solid immersion lens at a tip thereof and an object lens within it, and the movable plate jointly and thereby positioning the solid immersion lens and the observation port right below an observation position in a chip fabricated in the wafer; and
raising the SIL system toward the wafer prober to pass the solid immersion lens through the observation port of the movable plate and bring the solid immersion lens into close contact with the back of the wafer.
